(19) United States
(12) Patent Application Publication
(10) Pub. No.: US 2007/0187744 A1
(43) Pub. Date: Aug. 16, 2007

(54) Integrated circuits, memory device, method of producing an integrated circuit, method of producing a memory device, memory module

(76) Inventor: Franz Kreupl, Muenchen (DE)

Correspondence Address: SLATER & MATSIL LLP, 17950 PRESTON ROAD, SUITE 1000, DALLAS, TX, 75252, US

(21) Appl. No.: 11/699,744

(22) Filed: Jan. 30, 2007

(30) Foreign Application Priority Data
Jan. 30, 2006 (DE) 10 2006 004 218.2

(51) Int. Cl. H01L 29/76

(52) U.S. Cl. 257/314; 257/E29.3

(57) ABSTRACT

The invention relates to integrated circuits, a memory device, a method of producing an integrated circuit, a method of producing a memory device, and a memory module.

This application claims priority to German Patent Application 10 2006 004 218.2, which was filed Jan. 30, 2006 and is incorporated herein by reference.

### TECHNICAL FIELD

An embodiment of the invention generally relates to integrated circuits, a memory device, a method of producing an integrated circuit, a method of producing a memory device, and a memory module.

### BACKGROUND

In the development of memory elements, it is desirable to develop or improve nonvolatile memory cells (NVM cells), that is to say memory cells in which a state stored by means of one-time programming of/writing to the cell is maintained over a long period of time (typically≧10 years) without requiring regular refreshing of the cell content, such as rewriting with the same information.

### SUMMARY OF THE INVENTION

In accordance with one exemplary embodiment of the invention, an integrated circuit is provided. The integrated circuit includes a memory device. The memory device includes at least one electrically conductive layer formed in or on a substrate; at least one spacer which is formed on the substrate and which is formed in such a way that the at least one electrically conductive layer is arranged alongside the at least one spacer; at least one carbon layer which is formed at least over a partial region of the substrate and which crosses the at least one electrically conductive layer. The at least one carbon layer is at least partly formed on the at least one spacer in such a way that an interspace is formed between the at least one carbon layer and the at least one electrically conductive layer crossed by the at least one carbon layer, and wherein the at least one carbon layer is configured in such a way that it can be brought into contact with the at least one crossed electrically conductive layer.

### BRIEF DESCRIPTION OF THE DRAWINGS

In the figures, identical reference symbols generally designate the same component parts throughout the various views. The drawings are not necessarily true to scale. The main emphasis is instead generally placed on illustrating the principles of an embodiment of the invention. In the description below, various exemplary embodiments of the invention are described with reference to the following drawings, in which:

FIG. 1A shows a cross-sectional view of a memory device in accordance with one exemplary embodiment of the invention;

FIG. 1B and FIG. 1C show cross-sectional views of the memory device from FIG. 1A during other operating states;

FIG. 2 shows a layout illustration of the memory device from FIG. 1A;

FIG. 3A to FIG. 3F show various process steps during a method of producing a memory device in accordance with one exemplary embodiment of the invention;

FIG. 4A shows a cross-sectional view of a memory device in accordance with another exemplary embodiment of the invention;

FIG. 4B and FIG. 4C show cross-sectional views of the memory device from FIG. 4A during other operating states;

FIG. 5 shows a layout illustration of the memory device from FIG. 4A; and

FIG. 6A and FIG. 6B show memory modules in accordance with exemplary embodiments of the invention.

### DETAILED DESCRIPTION OF ILLUSTRATIVE EMBODIMENTS

One important branch of semiconductor technology is the development of memory cells or memory devices composed of one or more such memory cells, such as the development of elements for storing data, generally in the form of binary information units, i.e., bits (binary digits). In this context, writing to or programming a memory cell is to be understood to mean that a datum (e.g., a bit) is “written” into the cell, that is to say stored. Furthermore, reading or erasing a memory cell is to be understood to mean that the content of the memory cell, i.e., the stored information, is read out or erased, respectively. Furthermore, a read/write operation is also referred to as a cycle, and the time between the beginning of a read/write operation and the beginning of a further read/write operation is referred to as the cycle time.

Important characteristics of a memory cell in an electronic device are, inter alia, low (production) costs, the nonvolatility of the memory cell (the capability of permanently storing data or information even after a supply voltage or a supply current has been shut off), a low energy consumption and a high speed.

A major aim in the development of memory elements is to develop and improve nonvolatile memory cells (NVM cells), memory cells in which a state stored by means of one-time programming of/writing to the cell is maintained over a long period of time (typically≧10 years) without requiring regular refreshing of the cell content, such as rewriting with the same information.

Conventional memory technologies are, e.g., read only memory (ROM), programmable read only memory (PROM), erasable programmable read only memory (EPROM), electrically erasable programmable read only memory (EEPROM), dynamic random access memory (DRAM) and static random access memory (SRAM).

ROM is relatively cost-effective but not rewritable.

PROM can be electrically programmed, but only one single write operation or write cycle can be performed.

EPROM has read operations or read cycles which are relatively fast in comparison with ROM read cycles or PROM read cycles. However, EPROM has relatively long erase times, and the reliability of EPROM is afforded only over a few iterative read/write cycles.

EEPROM (or “flash”) is cost-effective and has a low energy consumption, but has long write cycles (of the order of magnitude of milliseconds) and also a low relative speed in comparison with DRAM or SRAM. Moreover, flash has only a finite number of read/write cycles, which results in low, long-term reliability.

ROM, PROM, EPROM and EEPROM are nonvolatile memory technologies, where the information stored in the memory cells of the memory is maintained when the power supply to the memory is interrupted.

In the case of DRAM, information items are stored in the form of charges on transistor gates, such that the transistor gates operate as capacitors. On account of discharge operations in the capacitors, however, the stored charge regularly has to be electrically “refreshed” at intervals of a few milliseconds (so-called refresh operation). This results in a higher complexity of the system design since separate circuitry is required for refreshing the memory contents.

In the case of SRAM, the data do not have to be refreshed, and SRAM is fast compared with DRAM. However, SRAM has a low memory density and is more expensive than DRAM.

Both SRAM and DRAM are volatile memory technologies, such that the memory loses the information stored in the memory cells when the power supply to the memory is interrupted.

To summarize, it can be stated that currently existing memory technologies are either nonvolatile, but do not permit random access and have a low memory density, high costs and a limited capability for multiple write operations with high reliability of the circuit function; or they are volatile and, in this case, make the system design more difficult or have a low memory density.

Technologies that have arisen more recently have attempted to eliminate the disadvantages mentioned above. By way of example, magnetic random access memories (MRAM) utilize the orientation of the magnetization of a ferromagnetic region for producing a nonvolatile memory cell. Ferroelectric random access memories (FRAM) analogously utilize the orientation of the polarization of a ferroelectric region for producing a nonvolatile memory cell.

MRAM uses a magnetoresistive memory element, with utilization of the anisotropic magnetoresistance or the giant magnetoresistance (GMR) of ferromagnetic materials, thereby achieving nonvolatility of the memory element. Another type of MRAM memory cell, based on magnetic tunnel junctions (MTJ), has likewise been investigated but has not led to MRAM devices commercialized on an industrial scale.

In the case of FRAM, a circuit architecture similar to DRAM is used, but the circuit architecture uses a thin film ferroelectric capacitor. The capacitor is intended to retain its electrical polarization after an externally applied electric field is removed, with the result that a nonvolatile memory can be realized.

Both MRAM and FRAM have a relatively high resistance and a low memory density. An additional disadvantage of FRAM consists in the large memory cell size and the associated difficulty of producing FRAM memory cells on a large scale as integrated components.

Another nonvolatile memory technology is phase change memory (PCM). This technology stores information items by means of a structural phase change in thin film alloys, which alloys contain elements such as, e.g., selenium or tellurium. The alloys are intended to remain stable both in the crystalline state and in the amorphous state, thereby enabling a bistable switch to be formed. Whereas the condition of nonvolatility is met in the case of PCM, this technology does appear to involve the drawbacks that the memory elements are slow in operation, and are difficult to produce, and that the reliability of the memory elements has not sufficed hitherto for commercialization of this technology.

Another memory technology that has likewise been proposed is so-called molecular wire crossbar memory (MWCM) technology. This approach provides for using molecules as bistable switches. In this case, two wires comprising metal or semiconducting material enclose a layer of molecules or molecular compounds in sandwichlike fashion. The idea is to use chemical compounds (chemical assembly) and electrochemical oxidations and reductions to realize an “on” state and “off” state, respectively. However, this type of memory requires highly specialized wire junctions, and the nonvolatility property is not permanently maintained on account of the inherent instability of redox processes.

Electromechanical memory devices have recently been proposed which use nanoscopic wires such as, e.g., single-walled carbon nanotubes (SWCNT) for forming crossbar junctions, in order to serve as memory cells. These devices are referred to hereinafter as nanotube wire crossbar memories (NTWCMs). In the case of the NTWCM devices, memory cells are realized by arranging individual single-walled nanotube wires in suspended fashion over other wires, the suspended nanotube wires being applied on supports. Electrical signals are applied to one wire or to both wires, the signals having the effect that the wires attract or repel one another. Each physical state (i.e., mutually attracting wires or mutually repelling wires) corresponds to an electrical state in this case. Mutually repelling wires represent an open circuit connection. Mutually attracting wires, by contrast, represent a closed state, an equidirectional connection being formed. If the electrical voltage is removed from the junction, then the wires (e.g., on account of the van der Waals bonds) remain in their physical (and thus electrical) state, whereby a nonvolatile memory cell is formed.

The NTWCM devices proposed hitherto are based on directional growth or chemical self-assembly techniques for growing the individual nanotubes which are required for the memory cells. These techniques are now thought to be difficult to apply on a commercial scale with the use of modem technology. What is more, said techniques may have inherent limitations, for example with regard to the length of nanotubes which can be grown reliably using said techniques. In addition, it may be difficult to control the statistical variance of the geometries of nanotube wires grown in this way.

In a further development of the NTWCM devices, the suspended nanoscopic wires used in the NTWCM devices are replaced by ribbons formed from a matted layer of nanotubes or a nonwoven fabric structure composed of nanotubes. These devices are referred to hereinafter as nanotube belt structures or nanotube ribbon crossbar memories (NTRCMs). These nanotube belt structures are thought to be simpler to produce at the desired integration levels and integration scales (measured in the number of devices produced), and to be simpler to control.

One disadvantage of the nanotube belt structures or NTRCMs, however, is that reliable operation is possible only with difficulty since, in the case of the structures, there are always some nanotubes which are too short and therefore possibly do not extend over the entire interspace toward the other side. During an erase operation of the memory cell, although the majority of the nanotubes are then repelled from the contact, one or more nanotubes remain contact-connected, however, which has the effect that a stored bit cannot be erased.

In accordance with one exemplary embodiment of the invention, an integrated circuit is provided. The integrated circuit includes a memory device. The memory device includes: at least one electrically conductive layer formed in or on a substrate; at least one spacer which is formed on the substrate and which is formed in such a way that the at least one electrically conductive layer is arranged alongside the at least one spacer; at least one carbon layer which is formed at least over a partial region of the substrate and which crosses the at least one electrically conductive layer, wherein the at least one carbon layer is at least partly formed on the at least one spacer in such a way that an interspace is formed between the at least one carbon layer and the at least one electrically conductive layer crossed by the at least one carbon layer, and wherein the at least one carbon layer is configured in such a way that it can be brought into contact with the at least one crossed electrically conductive layer.

In a method of producing a memory device in accordance with another exemplary embodiment, at least one electrically conductive layer is formed in or on a substrate. Furthermore, at least one spacer is formed on the substrate in such a way that the at least one electrically conductive layer is arranged alongside the at least one spacer. Furthermore, at least one carbon layer is formed at least over a partial region of the substrate, where at least one carbon layer crosses the at least one electrically conductive layer. The at least one carbon layer is at least partly formed on the at least one spacer in such a way that an interspace is formed between the at least one carbon layer and the at least one electrically conductive layer crossed by the at least one carbon layer. The at least one carbon layer is configured in such a way that it can be brought into contact with the at least one crossed electrically conductive layer.

Another exemplary embodiment of the invention provides a method of producing an integrated circuit. In the method, at least one electrically conductive layer is formed in or on a substrate. Furthermore, at least one spacer is formed on the substrate in such a way that the at least one electrically conductive layer is arranged alongside the at least one spacer. Furthermore, at least one carbon layer is formed at least over a partial region of the substrate, where at least one carbon layer crosses the at least one electrically conductive layer. The at least one carbon layer is at least partly formed on the at least one spacer in such a way that an interspace is formed between the at least one carbon layer and the at least one electrically conductive layer crossed by the at least one carbon layer. The at least one carbon layer is configured in such a way that it can be brought into contact with the at least one crossed electrically conductive layer.

Another exemplary embodiment of the invention provides a memory device. The memory device includes: at least one electrically conductive layer formed in or on a substrate; at least one spacer which is formed on the substrate and which is formed in such a way that the at least one electrically conductive layer is arranged alongside the at least one spacer; at least one carbon layer which is formed at least over a partial region of the substrate and which crosses the at least one electrically conductive layer. The at least one carbon layer is at least partly formed on the at least one spacer in such a way that an interspace is formed between the at least one carbon layer and the at least one electrically conductive layer crossed by the at least one carbon layer. The at least one carbon layer is configured in such a way that it can be brought into contact with the at least one crossed electrically conductive layer.

Another exemplary embodiment of the invention provides a memory module. The memory module includes a plurality of integrated circuits. At least one integrated circuit of the plurality of integrated circuits includes a memory device, which memory device includes: at least one electrically conductive layer formed in or on a substrate; at least one spacer which is formed on the substrate and which is formed in such a way that the at least one electrically conductive layer is arranged alongside the at least one spacer; at least one carbon layer which is formed at least over a partial region of the substrate and which crosses the at least one electrically conductive layer. The at least one carbon layer is at least partly formed on the at least one spacer in such a way that an interspace is formed between the at least one carbon layer and the at least one electrically conductive layer crossed by the at least one carbon layer. The at least one carbon layer is configured in such a way that it can be brought into contact with the at least one crossed electrically conductive layer.

In accordance with another embodiment of the invention, the memory module is a stackable memory module in which at least some integrated circuits of the plurality of integrated circuits are stacked one above the other.

In accordance with another exemplary embodiment of the invention, the memory device is an electromechanical memory device.

In accordance with another exemplary embodiment of the invention, a nonvolatile electromechanical memory device similar to the NTWCM devices or NTRCM devices described above is provided, but instead of nanotubes (in the case of NTWCM) or ribbons (in the case of NTRCM) one or a plurality of contiguous carbon layers are used as switching elements in the memory device or in a memory cell of the memory device.

The functioning of an electromechanical memory device in accordance with one exemplary embodiment of the invention is based, inter alia, on the fact that electrical signals (e.g., electrical voltages) are applied to a bottom electrical contact or a bottom electrode (the bottom electrical contact or the bottom electrode is formed by an electrically conductive layer formed in or on a substrate) and/or to a top electrical contact or a top electrode (the top electrical contact or the top electrode is formed by a carbon layer), which signals have the effect that the two electrodes attract or repel one another. In this case, the carbon layer forming the top electrode is configured in such a way that it can be brought into contact with the bottom electrode, such as the electrically conductive layer. Furthermore, if the two electrodes mutually attract one another on account of electrical or electrostatic interactions when suitable electrical signals are present, the carbon layer above the electrically conductive layer can deform until it comes into contact with the electrically conductive layer. Conversely, upon electrical repulsion of the two electrodes, the carbon layer can again deform in the opposite direction, so that the contact with the electrically conductive layer can be released. This operation can be repeated multiple times.

As mentioned in connection with the NTWCM devices or NTRCM devices, each physical state (i.e., mutually attracting electrodes or mutually repelling electrodes) corresponds to an electrical state. Mutually repelling electrodes represent an open circuit connection. Mutually attracting electrodes (or contact-connected electrodes), by contrast, represent a closed state, it being possible for an equidirectional connection to be formed. If the electrical voltage is removed from the junction, then the electrodes, in particular the carbon layer forming the top electrode, (e.g., on account of van der Waals bonds) remain in their physical (and thus electrical) state, whereby a nonvolatile memory cell is formed.

An electromechanical memory device in accordance with one exemplary embodiment of the invention can be interpreted as a hybrid memory device which combines electrical effects (generation of attracting or repelling electric fields by application of electrical signals/voltages to electrical contacts) with mechanical effects (mechanical, reversible deformation of a carbon layer) in order to store information items or data in nonvolatile fashion or permanently.

In accordance with another exemplary embodiment of the invention, the carbon layer clearly forms a switching element or a switch. The switch can be switched back and forth by application of electrical signals (voltages) to an electrically conductive layer and/or to the carbon layer between an open state (no contact with the electrically conductive layer) and a closed state (in contact with the electrically conductive layer). In this case, the switching back and forth between open and closed states may be effected at a high speed, which, in accordance with another exemplary embodiment of the invention, may be of the order of magnitude of approximately 1 Hz to 10 GHz, so that the electromechanical memory device can advantageously be used for high speed applications.

In accordance with another exemplary embodiment of the invention, the use of a contiguous carbon layer means that the favorable properties of the material carbon (e.g., strength, electrical conductivity, chemical inertness) are combined with the, for example, in comparison with nanotubes, significantly simpler processability of layer structures. By way of example, in accordance with one exemplary embodiment of the invention, it is possible to use conventional lithographic techniques and/or etching techniques for patterning the carbon layer, in contrast to conventional techniques in which nanotubes have to be grown at precisely defined locations in precisely defined directions, which requires a high process-technological outlay.

In accordance with another exemplary embodiment of the invention, the use of a carbon layer as a switching element means that a bit stored in an electromechanical memory device can be reliably erased since, in the event of an electrical or electrostatic repulsion brought about by application of electrical signals, the contact between the electrically conductive layer and the carbon layer can be reliably released, or cancelled, in contrast to conventional devices in which, as mentioned above, individual nanotubes remain contact-connected during the erase operation and, consequently, the bit is not reliably erased.

In accordance with another exemplary embodiment of the invention, neither vacuum bonding nor oxidation of the contact areas is effected when a carbon layer is used as a switching element. If the switch or the switching element comprised metal, then it is known that bonding of the contact areas can occur in this case. Oxidation of the contact area, as may occur when using metals and polysilicon, would result in the resistances changing over the course of time and, consequently, a read-out of the state being more difficult. These problems are avoided, however, by the use of a carbon layer in the electromechanical memory device.

In accordance with another exemplary embodiment of the invention, the substrate has a dielectric material or a dielectric. In other words, an electrically insulating material may be used as the substrate material.

In accordance with another exemplary embodiment of the invention, the at least one electrically conductive layer is formed as an electrically conductive carbon layer, such as a metallic carbon layer.

In accordance with another exemplary embodiment of the invention, the at least one electrically conductive layer has a refractory material, a material having a high melting point or heat-resistant material, for example a refractory metal.

In accordance with another exemplary embodiment of the invention, the at least one electrically conductive layer has one of the following materials: tantalum (Ta), tantalum nitride (TaN), titanium (Ti), titanium nitride (TiN), molybdenum (Mo).

In accordance with another exemplary embodiment of the invention, the at least one spacer has a refractory material, a material having a high melting point or heat-resistant material.

In accordance with another exemplary embodiment of the invention, a spacer has one of the following materials: titanium (Ti), tantalum (Ta), tungsten (W), silicon nitride (Si₃N₄) or a carbide material.

In accordance with another exemplary embodiment of the invention, carbon is used as material for a spacer.

In accordance with another exemplary embodiment of the invention, a spacer may have, parallel to the substrate surface, for example, a rectangular cross section or square cross section. As an alternative, the spacer may have, parallel to the substrate surface, some other cross-sectional form.

In accordance with another exemplary embodiment of the invention, a spacer formed on the substrate, e.g., a spacer having a square cross section, may have, parallel to the substrate surface, a lateral (i.e., parallel to the substrate surface) extent which is of the order of magnitude of the minimum feature size F of the technology used.

In accordance with another exemplary embodiment of the invention, the lateral extent of a spacer may be, for example, approximately 5 nm to 200 nm.

In accordance with another exemplary embodiment of the invention, a spacer has a thickness of approximately 1 nm to 100 nm. In this case, the thickness of a spacer can be understood to mean the extent of the spacer perpendicular to the substrate surface.

In accordance with another exemplary embodiment of the invention, the at least one carbon layer has an electrically conductive carbon material, for example a metallic carbon material. Therefore, in accordance with this exemplary embodiment, the carbon layer may alternatively be referred to as an electrically conductive carbon layer or metallic carbon layer.

In accordance with another exemplary embodiment of the invention, the at least one carbon layer has a thickness of approximately 1 nm to 100 nm.

In accordance with another exemplary embodiment of the invention, the at least one carbon layer may be formed with the aid of a deposition method.

In accordance with another exemplary embodiment of the invention, the method described below for the deposition of a carbon material may be used as a deposition method of forming the carbon layer. By way of example, an interior space of a process chamber can be heated to a predetermined temperature, for example, to a temperature of between approximately 400° C. and 1200° C. (for example, to 600° C. or 950° C.). Furthermore, the substrate, including the at least one electrically conductive layer formed in the substrate and also the plurality of spacers formed on the substrate, can be introduced into the process chamber, and the process chamber can be evacuated to a first predetermined pressure, which may be less than 1 Pa (Pascal), for example less than ⅛ Pa. Furthermore, a gas having at least carbon, for example an organic gas such as methane (CH₄), for example, may be introduced until a second predetermined pressure is reached, which may be higher than the first predetermined pressure. The second predetermined pressure may be, for example, between approximately 10 hPa and 1013 hPa, for example, between approximately 300 hPa and 700 hPa. The carbon material can be deposited on the spacers formed on the substrate, and on a sacrificial layer that is possibly formed on the substrate and/or the at least one electrically conductive layer and is composed of the carbon-containing gas, for example the methane gas. The deposition of the carbon material may be optionally followed by a heat treatment at approximately 1050° C., for example.

In accordance with another exemplary embodiment of the invention, it is provided that an electromechanical memory device has a plurality of electrically conductive layers formed in or on the substrate, a plurality of spacers formed on the substrate, and also a plurality of carbon layers, and that the electrically conductive layers, the plurality of spacers and the plurality of carbon layers are arranged in such a way that a crossbar array is formed. An array in which electrically conductive layers and carbon layers cross one another is formed in accordance with this exemplary embodiment.

Such a crossbar array clearly forms an array of a plurality of electromechanical memory cells in which an individual memory cell is realized by a crossbar junction between an electrically conductive layer (or metallic interconnect) and a carbon layer (carbon interconnect) crossing the interconnect. In this case, the electrically conductive layer forms a bottom contact or a bottom electrode, and the carbon layer correspondingly forms a top contact or a top electrode.

A crossbar array comprising electromechanical memory cells in accordance with one exemplary embodiment of the invention may be interpreted as a memory cell core circuit. With the aid of an access circuit coupled to the core circuit, more precisely to the electrodes of the core circuit, the core circuit may be allocated array addresses in order to select individual memory cells of the electromechanical memory device. In other words, individual electrodes of the memory cell core circuit can be driven with the aid of the access circuit. Such an access circuit may be provided using standard semiconductor circuit elements.

In accordance with another exemplary embodiment of the invention, in each case two adjacent spacers of a plurality of spacers (e.g., in a crossbar array) may have a lateral spacing which is of the order of magnitude of the minimum feature size F of the technology used. In accordance with one exemplary embodiment, the lateral spacing between two adjacent spacers may be, for example, approximately 5 nm to 1000 nm.

In accordance with another exemplary embodiment of the invention, the at least one carbon layer is patterned using a lithography method and/or an etching method.

In accordance with another exemplary embodiment of the invention, prior to the formation of the carbon layer, at least one sacrificial layer is formed on the substrate and/or on the at least one electrically conductive layer.

In accordance with another exemplary embodiment of the invention, the sacrificial layer may have silicon dioxide material, for example, which may be applied by means of a deposition method or a chemical vapor deposition method such as e.g. PECVD (plasma enhanced chemical vapor deposition), or by means of a spin-on coating method (spin-on method). Optionally, it is also possible to apply other materials such as, for example, amorphous silicon or aluminum oxide by means of PECVD or atomic layer deposition (ALD) as a sacrificial layer, in which case the abovementioned materials can be removed selectively with respect to the surroundings by means of an etching method, e.g., a wet-chemical etching method (wet etching).

With the aid of the thickness of the sacrificial layer, which thickness may be, for example, within the range from approximately 1 nm to 100 nm in accordance with another exemplary embodiment, the spacing between the bottom contact electrode (electrically conductive layer) and the top contact electrode (carbon layer) may be defined such that the spacing can be set, to put it another way selected, arbitrarily. In accordance with another exemplary embodiment of the invention, the region around the supporting locations (i.e., around the spacers) can be uncovered again after the formation of the carbon layer, in accordance with one exemplary embodiment, for example, by means of chemical mechanical polishing (CMP) or in accordance with another exemplary embodiment by means of phototechnology and wet-chemical removal (wet etching) of the sacrificial layer.

In accordance with another exemplary embodiment of the invention, the interspace between the at least one carbon layer and the at least one electrically conductive layer crossed by the at least one carbon layer is formed by removal of the sacrificial layer formed on the substrate and/or on the at least one electrically conductive layer.

In accordance with another exemplary embodiment of the invention, the removal of the sacrificial layer may be effected with the aid of a wet etching method.

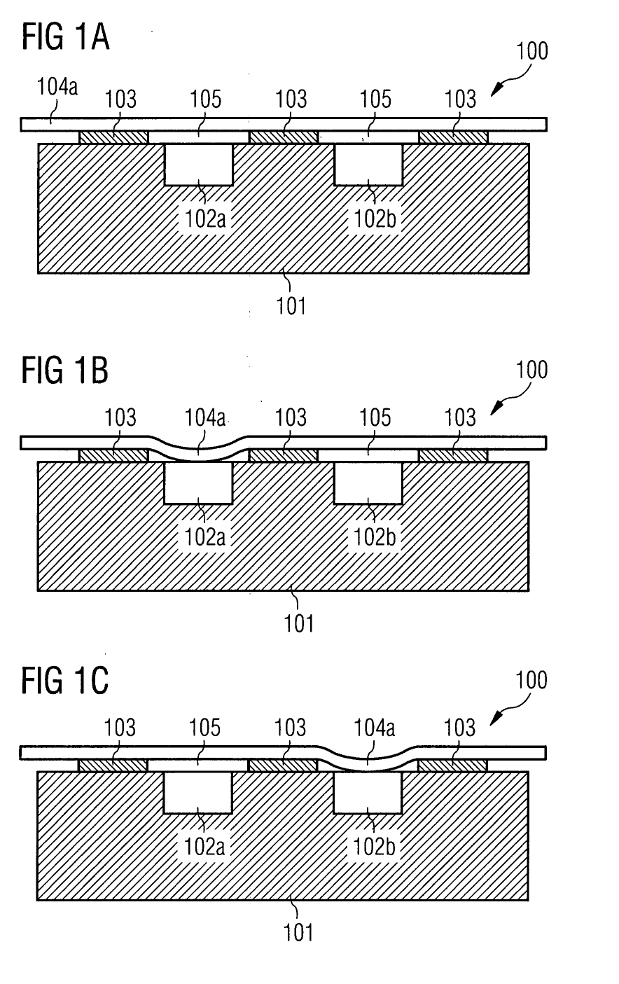

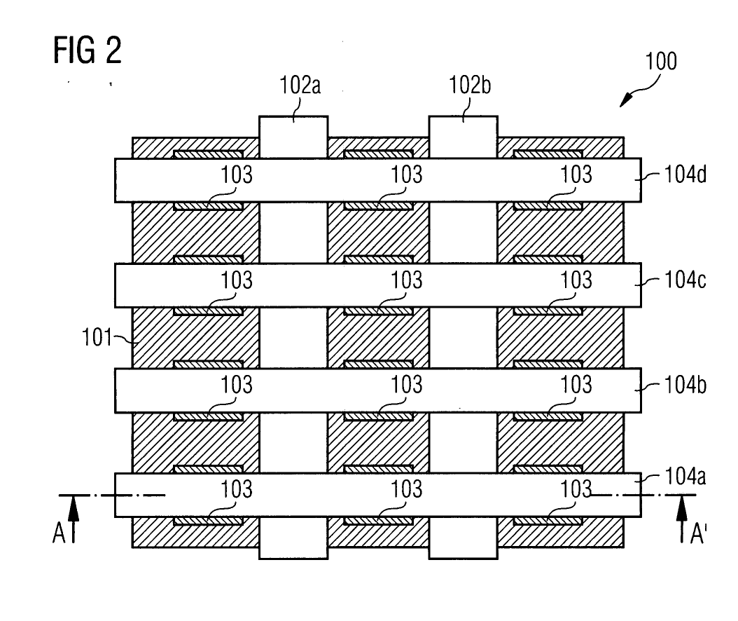

FIG. 1A shows an electromechanical memory device 100 in accordance with one exemplary embodiment of the invention. The memory device 100 may be part of an integrated circuit. The electromechanical memory device 100 has a substrate 101 formed from a dielectric material (dielectric) or an electrically insulating material. A first electrically conductive layer 102a and a second electrically conductive layer 102b are formed in the substrate 101. The first electrically conductive layer 102a and the second electrically conductive layer 102b may have a refractory metal, i.e., a metallic material having a high melting point, such as, e.g., tantalum, tantalum nitride, titanium, titanium nitride, molybdenum or other suitable electrically conductive materials such as e.g. metallic carbon. The first electrically conductive layer 102a and the second electrically conductive layer 102b clearly form a first electrical interconnect or a first bottom electrode 102a and a second electrical interconnect or a second bottom electrode 102b of the electromechanical memory device 100, which interconnects or bottom electrodes 102a and 102b and run essentially parallel to one another and perpendicular to the plane of the drawing of FIG. 1A, which can be seen from the layout illustration of the electromechanical memory device 100 as shown in FIG. 2, which layout illustration reveals the illustration shown in FIG. 1A as cross-sectional view along the broken line A-A′in FIG. 2.

FIG. 2 illustrates that the electromechanical memory device 100 of the exemplary embodiment shown is formed as a crossbar array.

The electromechanical memory device 100 shown in FIG. 1A and FIG. 2 has, by way of example, two electrically conductive layers 102a and 102b serving as bottom electrodes. In alternative embodiments of the invention, an electromechanical memory device may also have a different number of electrically conductive layers. A memory device formed as a crossbar array may have, e.g., a multiplicity (typically of the order of magnitude of 10⁶ cm⁻² to 10¹⁰ cm⁻²) of electrically conductive layers (bottom electrodes).

The electromechanical memory device 100 furthermore has a plurality of spacers 103 which are formed on the substrate 101 and which are arranged in such a way that the first electrically conductive layer 102a and the second electrically conductive layer 102b are in each case arranged alongside or between at least two spacers 103. It can be seen from the layout illustration of the memory device 100 as shown in FIG. 2 that the spacers 103 are arranged in rows and columns in a regular rectangular array. The spacers 103 are clearly arranged on grid locations of a rectangular grid, between two columns of the grid, and an electrically conductive layer is arranged parallel to the grid columns. The spacers 103 may have a thickness (perpendicular to the substrate surface) of approximately 1 nm to 100 nm. Furthermore, the spacers 103 may have a lateral extent (along the grid axes) of approximately 5 nm to 200 nm, and the distance between two adjacent spacers 103 along the grid axes may be approximately 5 nm to 1000 nm, where two “adjacent” spacers are to be understood in this context to mean two spacers on a nearest neighbor (NN) grid location of the rectangular grid. The spacers 103 may have refractory material, a material having a high melting point or heat-resistant material, e.g., titanium (Ti), tantalum (Ta), tungsten (W), silicon nitride (Si₃N₄) or a carbide material. As an alternative, the spacers may have carbon.

The electromechanical memory device 100 furthermore has a plurality of electrically conductive carbon layers, a first carbon layer 104a of which is shown in FIG. 1a. A second carbon layer 104b, a third carbon layer 104c and a fourth carbon layer 104d can be seen from the layout illustration of the electromechanical memory device 100 as shown in FIG. 2.

The first carbon layer 104a, the second carbon layer 104b, the third carbon layer 104c and the fourth carbon layer 104d may in each case have a thickness (perpendicular to the substrate surface) of approximately 1 nm to 100 nm.

Each individual one of the four carbon layers 104a, 104b, 104c and 104d is formed above a partial region of the substrate 101 and crosses the first electrically conductive layer 102a and the second electrically conductive layer 102b. In this case, the carbon layers 104a, 104b, 104c and 104d are respectively formed on corresponding spacers in such a way that an interspace 105 is formed between the carbon layer 104a, 104b, 104c and 104d, respectively, and the electrically conductive layer 102a or 102b crossed by the respective carbon layer. In other words, with the aid of the spacers 103, a spacing is created between the carbon layers 104a, 104b, 104c and 104d, respectively, and the first electrically conductive layer 102a or the second electrically conductive layer 102b, with the result that the carbon layers 104a, 104b, 104c and 104d, respectively, do not touch the first electrically conductive layer 102a or the second electrically conductive layer 102b.

Clearly, the first carbon layer 104a, the second carbon layer 104b, the third carbon layer 104c and the fourth carbon layer 104d form a first top electrode 104a, a second top electrode 104b, a third top electrode 104c and a fourth top electrode 104d. The top electrodes are supported by the spacers 103 and are arranged in a suspended fashion over the bottom electrodes 102a and 102b.

The first carbon layer 104a, the second carbon layer 104b, the third carbon layer 104c and the fourth carbon layer 104d have an electrically conductive carbon material or metallic carbon and clearly form a first top electrode 104a, a second top electrode 104b, a third top electrode 104c and a fourth top electrode 104d, respectively, of the electromechanical memory device 100. The top electrodes or carbon layers 104a, 104b, 104c and 104d in this case run essentially parallel to one another and are clearly supported by the spacers 103.

The electromechanical memory device 100 shown in FIG. 1A and FIG. 2 has, by way of example, four carbon layers 104a, 104b, 104c and 104d serving as top electrodes. In alternative embodiments of the invention, the memory device may also have a different number of carbon layers (or top electrodes). A memory device formed as a crossbar array may have, e.g., a multiplicity (typically of the order of magnitude of 10⁶ cm⁻² to 10¹⁰ cm⁻²) of electrically conductive carbon layers (top electrodes).

FIG. 2 shows the memory device 100 formed as a crossbar array, in a layout illustration, wherein it can be discerned that, on account of the crossbar structure, the first electrically conductive layer 102a and the second electrically conductive layer 102b run parallel to one another, and that the four carbon layers 104a, 104b, 104c and 104d which cross the first electrically conductive layer 102a and the second electrically conductive layer 102b and are supported by the spacers 103 likewise run parallel to one another. Furthermore, the illustration shows that the carbon layers 104a, 104b, 104c and 104d cross or intersect the first electrically conductive layer 102a and the second electrically conductive layer 102b in each case at an angle of 90°, that is to say perpendicularly.

In accordance with alternative exemplary embodiments of the invention, the abovementioned features may be partly or wholly omitted, that is to say that one or a plurality of electrically conductive layers may, e.g., run obliquely (non-parallel) to one another and/or individual or a plurality of carbon layers may likewise run obliquely (non-parallel) to one another. Furthermore, one or a plurality of carbon layers (top electrodes) of a memory device may cross or intersect one or a plurality of electrically conductive layers (bottom electrodes) of the memory device at an angle that deviates from 90°.

FIG. 2 further shows that all the carbon layers, the first carbon layer 104a, the second carbon layer 104b, the third carbon layer 104c and the fourth carbon layer 104d, cross both the first electrically conductive layer 102a (first bottom electrode) and the second electrically conductive layer 102b (second bottom electrode). In accordance with alternative exemplary embodiments, however, it is also possible for one or a plurality of carbon layers to cross in each case only a portion of the electrically conductive layers. By way of example, in an alternative exemplary embodiment, the first carbon layer 104a and the third carbon layer 104c may cross only the first electrically conductive layer 102a, while the second carbon layer 104b and the fourth carbon layer 104d cross only the second electrically conductive layer 102b.

The considerations above can be applied in an analogous manner to electromechanical memory devices having any desired number of electrically conductive layers (bottom electrodes) or carbon layers (top electrodes).

In the electromechanical memory device 100 shown in FIG. 1A, the first electrically conductive layer 102a (first interconnect) and the second electrically conductive layer 102b (second interconnect) are formed in the substrate 100 in such a way that they have in each case an upper surface that is coplanar with the upper surface of the substrate 100. In alternative embodiments (not shown) of the invention, the first electrically conductive layer 102a and the second electrically conductive layer 102b (and possibly further electrically conductive layers that are not shown) may also partly “project” from the substrate 101 or be formed on the substrate 101. The thickness of the spacers 103 may be chosen correspondingly such that even with electrically conductive layers 102a and 102b that wholly or partly project from the substrate 101 or are formed on the substrate 101, an interspace 105 is in each case formed between the first electrically conductive layer 102a or the second electrically conductive layer 102b and the electrically conductive carbon layers 104a, 104b, 104c, 104d.

The electromechanical memory device 100 shown in FIG. 1A and FIG. 2 may also be regarded as an array of individual (eight in the example shown) electromechanical memory cells, each individual electromechanical memory cell being realized by a crossbar junction.

The functioning of the electromechanical memory device 100 is explained in more detail below with reference to the illustrations shown in FIG. 1A, FIG. 1B and FIG. 1C.

It generally holds true that in the case of an electromechanical memory device such as the electromechanical memory device 100 shown in FIG. 1A, individual bits or the logic values (e.g., “0” or “1”) of individual bits can be stored by virtue of circuit connections which can be realized by the at least one electrically conductive layer and the at least one carbon layer being either open or closed. An open circuit connection may represent a logic “0”, for example, and a closed circuit connection may correspondingly represent a logic “1”.

FIG. 1A shows the electromechanical memory device 100 during a first operating state, in which the first carbon layer 104a (first top electrode) is in contact neither with the first electrically conductive layer 102a nor with the second electrically conductive layer 102b. Consequently, the first electrically conductive layer 102a clearly forms together with the first carbon layer 104a an open circuit connection (representing, e.g., a logic “0” of a first bit stored in the corresponding memory cell, the crossbar junction composed of the first electrically conductive layer 102a and the first carbon layer 104a, of the electromagnetic memory device 100), and the second electrically conductive layer 102b likewise forms together with the first carbon layer 104a an open circuit connection (representing a logic “0” of a second bit stored in the corresponding memory cell, the crossbar junction composed of the second electrically conductive layer 102b and the first carbon layer 104a, of the electromagnetic memory device 100).

To summarize, in the case of the first operating state shown in FIG. 1A, a logic “0” of a first bit is stored in a first memory cell of the memory device 100, which first memory cell is realized by the crossbar junction composed of the first electrically conductive layer 102a and the first carbon layer 104a, and a logic “0” of a second bit is stored in a second memory cell of the memory device 100, which second memory cell is realized by the crossbar junction composed of the second electrically conductive layer 102b and the first carbon layer 104a.

FIG. 1B shows the electromechanical memory device 100 during a second operating state, in which, in contrast to the operating state shown in FIG. 1A, the first carbon layer 104a (first top electrode) has been brought into contact with the first electrically conductive layer 102a (first bottom electrode), while the second electrically conductive layer 102b still has no contact with the first carbon layer 104a. The contact-connection of the first carbon layer 104a to the first electrically conductive layer 102a may be effected, for example, by suitable electrical signals being applied to the first electrically conductive layer 102a and/or to the first carbon layer 104a (e.g., with the aid of an access circuit), which electrical signals bring about an electrical or electrostatic attraction between the first electrically conductive layer 102a and the first carbon layer 104a. On account of the electrical or electrostatic attraction between the two layers mentioned above, a mechanical deformation of the first carbon layer 104a may occur in the region above the first electrically conductive layer 102a, with the result that the first carbon layer 104a clearly bends in the direction of the first electrically conductive layer 102a and makes contact with the first electrically conductive layer 102a, see FIG. 1B.

In contrast to the first operating state of the memory device 100 as shown in FIG. 1A, in the case of the second operating state of the memory device 100 as shown in FIG. 1B, the first electrically conductive layer 102a forms together with the first carbon layer 104a a closed circuit connection (representing a logic “1” of the first bit stored in the corresponding memory cell of the electromagnetic memory device 100). The contact-connected state is maintained even after the electrical signal or signals has or have been turned off.; The mechanical deformation of the first carbon layer 104a over the first electrically conductive layer 102a does not disappear without external action.

To summarize, in the case of the second operating state shown in FIG. 1B, a logic “1” of the first bit is stored in the first memory cell of the memory device 100, and the logic “0” of the second bit is still stored in the second memory cell of the memory device 100.

FIG. 1C shows the electromechanical memory device 100 during a third operating state, in which the contact of the first carbon layer 104a with the first electrically conductive layer 102a has been released again, while at the same time the first carbon layer 104a has been brought into contact with the second electrically conductive layer 102b. The contact of the first carbon layer 104a with the first electrically conductive layer 102a can be released by suitable electrical signals being applied to the first electrically conductive layer 102a and/or to the first carbon layer 104a (e.g., with the aid of an access circuit), which signals bring about an electrical or electrostatic repulsion between the first electrically conductive layer 102a and the first carbon layer 104a. On account of the electrical or electrostatic repulsion between the two layers mentioned above, a mechanical deformation of the first carbon layer 104a may occur, with the result that the latter clearly bends in a direction away from the first electrically conductive layer 102a and the contact with the first electrically conductive layer 102a is thus cancelled or released, see FIG. 1C. The first carbon layer 104a therefore assumes the state shown in FIG. 1A again above the first electrically conductive layer 102a.The first carbon layer 104a is contact-connected to the second electrically conductive layer 102b in the manner as described above in connection with FIG. 1B for the contact-connection of the first carbon layer 104a to the first electrically conductive layer 102a.

In the case of the operating state of the memory device 100 as shown in FIG. 1C, the first electrically conductive layer 102a forms together with the first carbon layer 104a as in FIG. 1A an open circuit connection (representing a logic “0” of the first bit), and the second electrically conductive layer 102b forms together with the first carbon layer 104a a closed circuit connection (representing a logic “1” of the second bit).

To summarize, in the case of the third operating state as shown in FIG. 1C, a logic “0” of the first bit is stored in the first memory cell of the memory device 100, and a logic “1” of the second bit is stored in the second memory cell of the memory device 100.

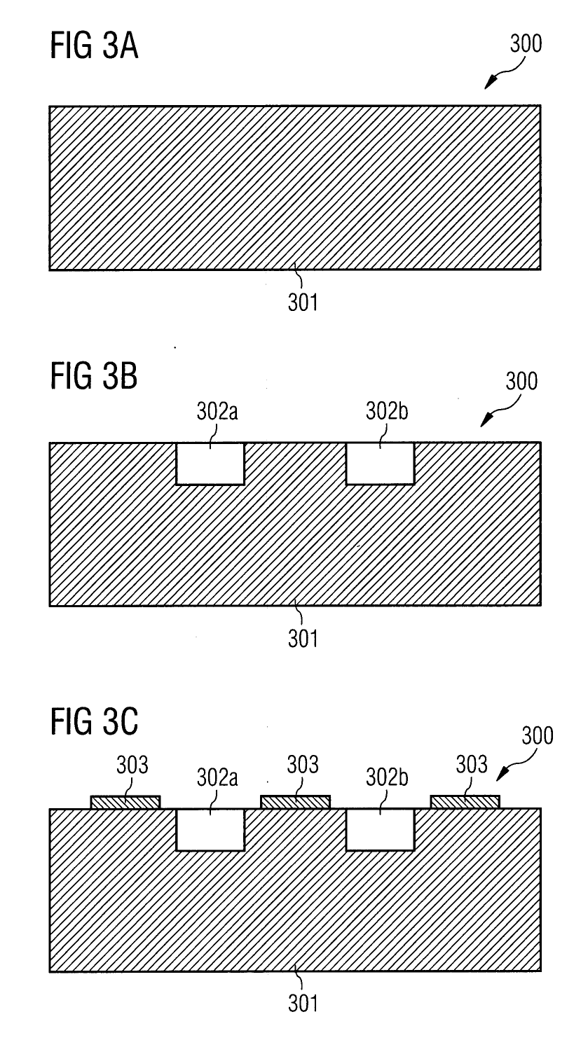

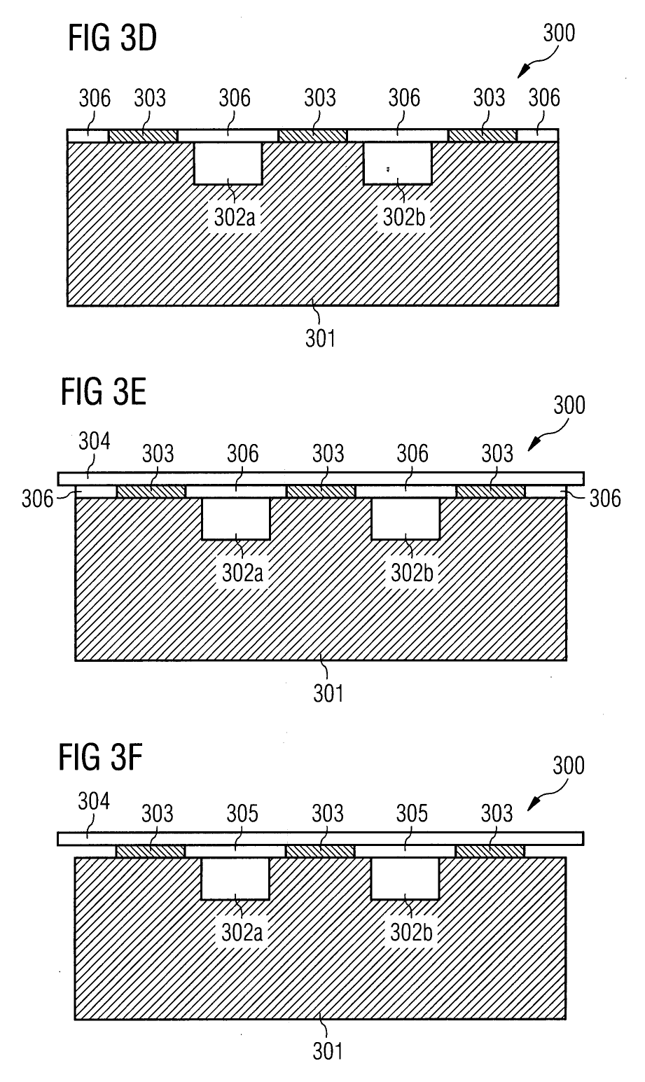

A description is given below, with reference to FIG. 3A to FIG. 3F, of a method of producing an electromechanical memory device 300 in accordance with one exemplary embodiment of the invention.

FIG. 3A shows a first process step, in which a substrate 301 is provided. The substrate 301 may have a dielectric material (dielectric) or an electrically insulating material.

FIG. 3B shows a further process step, in which a first electrically conductive layer 302a and a second electrically conductive layer 302b are formed in the substrate 301, the first electrically conductive layer 302a and the second electrically conductive layer 302b in each case having an upper surface that is coplanar with the upper surface of the substrate 301. The first electrically conductive layer 302a and the second electrically conductive layer 302b may be formed using conventional lithographic techniques, deposition methods and/or patterning methods, e.g., with the aid of a damascene method (that is to say etching of trenches in the substrate 301, filling of the trenches with electrically conductive material and planarization of the surfaces, e.g., by chemical mechanical polishing (CMP)).

In alternative embodiments of the invention, the first electrically conductive layer 302a and/or the second electrically conductive layer 302b may also project beyond the upper surface of the substrate 301 or be formed on the substrate 301. The first electrically conductive layer 302a and the second electrically conductive layer 302b may have a metallic carbon layer or a refractory metal, that is to say a metallic material having a high melting point such as, e.g., tantalum, tantalum nitride, titanium, titanium nitride, molybdenum or other suitable materials. The first electrically conductive layer 302a and the second electrically conductive layer 302b clearly form two electrical interconnects or two bottom electrodes of the electromechanical memory device 300. Interconnects run essentially parallel to one another and perpendicular to the plane of the drawing of FIG. 3B.

FIG. 3C shows a further process step, in which a plurality of spacers 303 are formed on the substrate 301, the spacers 303 being formed in such a way that the first electrically conductive layer 302a and the second electrically conductive layer 302b are in each case arranged between at least two spacers 303. The spacers 303 may have a thickness (perpendicular to the substrate surface) of approximately 1 nm to 100 nm. Furthermore, the spacers 303 may have a lateral extent of approximately 5 nm to 200 nm, and the distance between two spacers 303 may be approximately 5 nm to 1000 nm. The spacers 303 may have a carbon layer or a refractory material, a material having a high melting point or heat-resistant material, e.g., titanium (Ti), tantalum (Ta), tungsten (W), silicon nitride (Si₃N₄) or a carbide material.

The spacers 303 may be formed by application of a layer (e.g. with the aid of a deposition method) composed of one of the abovementioned materials and subsequent patterning (e.g. with the aid of a lithography method and/or etching method) of said layer.

FIG. 3D shows a further process step, in which, between the spacers 303, a sacrificial layer 306 (e.g., composed of silicon dioxide) is applied on the substrate 301, on the first electrically conductive layer 302a and on the second electrically conductive layer 302b (e.g., with the aid of a deposition method), the sacrificial layer 306 being formed in such a way that the upper surface of the sacrificial layer 306 is essentially coplanar with the upper surface of the spacers 303. In the example shown, the sacrificial layer 306 has essentially the same thickness as the spacers 303. This may be achieved, e.g., by means of a planarization method (e.g., chemical mechanical polishing, CMP).

FIG. 3E shows a further process step, in which a metallic (electrically conductive) carbon layer 304 is formed on the spacers 303 and on the sacrificial layer 306. The electrically conductive carbon layer 304 may be formed with the aid of a deposition method. A deposition method that may be used is, a method of depositing a carbon material in which, an interior space of a process chamber is heated to a predetermined temperature, for example, to a temperature of between approximately 400° and 1200° C. (for example, to approximately 600° C. or 950° C.). Furthermore, the substrate 301, including the first electrically conductive layer 302a formed in the substrate 301, the second electrically conductive layer 302b formed in the substrate 301, the plurality of spacers 303 formed on the substrate 301, and the sacrificial layer 306, may be introduced into the process chamber and the process chamber may be evacuated to a first predetermined pressure, which may be less than 1 Pa (Pascal), for example less than ⅛ Pa. Furthermore, a gas having at least carbon, an organic gas such as methane (CH₄), for example, may be introduced until a second predetermined pressure has been reached, which may be higher than the first predetermined pressure. The second predetermined pressure may lie, for example, between approximately 10 hPa and 1013 hPa, between approximately 300 hPa and 700 hPa. The carbon material may be deposited on the spacers 303 and also on the sacrificial layer 306 from the carbon-containing gas, for example the methane gas. After the deposition of the carbon material, a heat treatment at 1050° C., for example, may optionally be effected.

The electrically conductive carbon layer 304 may be formed in such a way that it has a thickness of approximately 1 nm to 100 nm, for example.

After the formation of the carbon layer 304, the latter is subsequently patterned in such a way that a crossbar structure is formed (cf. FIG. 2). The carbon layer 304 may be patterned e.g. using conventional lithographic techniques and/or etching methods.

FIG. 3F shows a further process step, in which the sacrificial layer 306 is removed, with the result that interspaces 305 are formed between the first electrically conductive layer 302a and the carbon layer 304 and between the second electrically conductive layer 302b and the carbon layer 304. The sacrificial layer 306 may be removed by means of a selective etching method (e.g., selective wet etching).

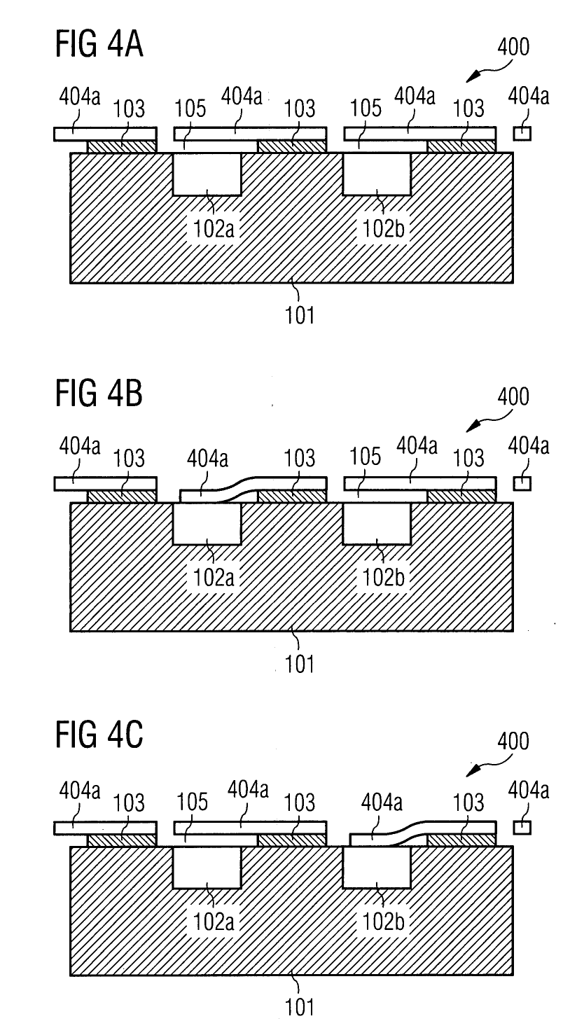

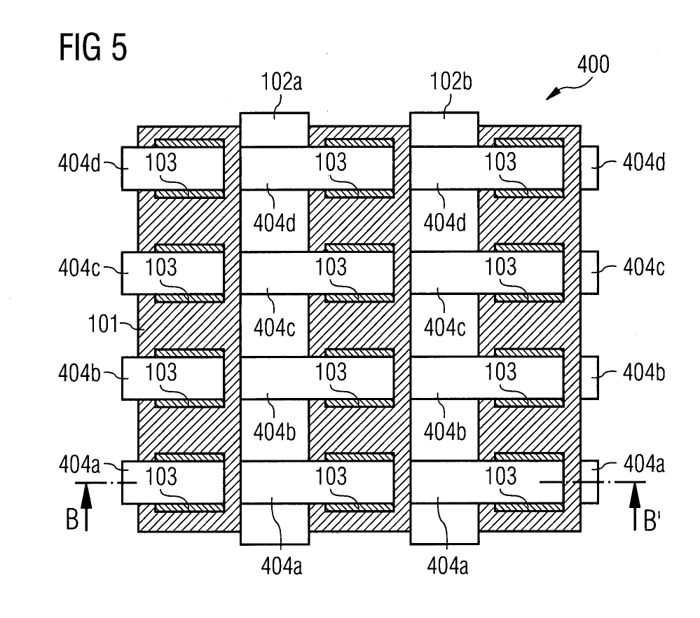

FIG. 4A shows a cross-sectional view of an electromechanical memory device 400 formed as a crossbar array in accordance with another exemplary embodiment of the invention. FIG. 5 shows a layout illustration of the electromechanical memory device 400, which layout illustration reveals the view shown in FIG. 4A as a cross section along the broken line B-B′.

The electromechanical memory device 400 shown in FIG. 4A and FIG. 5 differs from the electromechanical memory device 100 shown in FIG. 1A and FIG. 2 essentially in that the first carbon layer 104a of the electromechanical memory device 100, which crosses the first electrically conductive layer 102a and the second electrically conductive layer 102b, is replaced by four individual first carbon layers 404a in the case of the electromechanical memory device 400. Each of the four first carbon layers 404a being formed on a spacer 103 and, in the exemplary embodiment shown in FIG. 4A and FIG. 5, crossing the electrically conductive layer 102a or 102b (or other electrically conductive layers that are not shown) arranged on the left alongside the corresponding spacer 103. In other words, each of the four first carbon layers 404a is in each case carried only by one spacer 103 or supporting element. The respective first carbon layer 404a clearly forms an overhang or a cantilever-like structure above the corresponding electrically conductive layer 102a or 102b.It should be noted that the individual first carbon layers 404a are not connected to one another.

In each case four individual second carbon layers 404b, four individual third carbon layers 404c and four individual fourth carbon layers 404d are formed in an analogous manner in the case of the electromechanical memory device 400, as shown in FIG. 5.

The functioning of the electromechanical memory device 400 is identical to the electromechanical memory device 100 and is illustrated by the illustrations in FIG. 4A, FIG. 4B and FIG. 4C, which show three different operating states of the electromechanical memory device 400 analogously to FIG. 1A, FIG. 1B and FIG. 1C.

As explained for the electromechanical memory device 100 in connection with FIG. 1A, FIG. 1B and FIG. 1C, in the case of the electromechanical memory device 400 logic values (“0” or “1”) can be realized or stored by means of open or closed contacts between the carbon layers (top electrodes) 404a, 404b, 404c and 404d and the electrically conductive layers 102a and 102b (bottom electrodes). The formation of a closed contact between a carbon layer and an electrically conductive layer is achieved by application of suitable electrical signals to the corresponding electrically conductive layer and/or the corresponding carbon layer, so that a deformation of the corresponding carbon layer 404a, 404b, 404c or 404d (top electrode) occurs on account of electrical or electrostatic interactions, as a result of which said carbon layer bends in the direction toward the electrically conductive layer 102a or 102b (bottom electrode) and makes contact with the electrically conductive layer 102a or 102b. The release of the contact is effected as explained above correspondingly by application of suitable signals, so that an electrical or electrostatic repulsion occurs between the two electrodes.

As can be seen from FIG. 4B and FIG. 4C, since the carbon layers 404a, 404b, 404c and 404d are connected to the spacer 103 only on one side (on the right-hand side in the example shown, with the spacer 103 on the right alongside the corresponding electrically conductive layer 102a or 102b), in the case of a closed contact, the carbon layer, i.e., the top electrode, (the first carbon layer 404a in the cross-sectional views shown in FIG. 4B and FIG. 4C) is deformed, clearly bent, only at this one side. In the case of the electromechanical memory device 100, in which the first carbon layer 104a is connected to a spacer 103 on both sides, a closed contact results in a bending of the first carbon layer 104a on both sides (that is to say on the right and on the left alongside the electrically conductive layer 102a or 102b)(cf. FIG. 1B and FIG. 1C).

With the electromechanical memory device 400 shown in FIG. 4A to FIG. 5, it is possible, for example, to significantly reduce the strains in the carbon layers 404a, 404b, 404c and 404d that arise as a result of the mechanical deformation or the bending upon the closing of contacts.

A method similar to the method described in connection with FIG. 3A to FIG. 3F may be used for producing the electromechanical memory device 400 shown in FIG. 4A to FIG. 5, in which case, in contrast to the method described above, after the application of a carbon layer to the spacers 103 and the sacrificial layer, the carbon layer is patterned in such a way as to produce the four individual first carbon layers 404a, the four individual second carbon layers 404b, the four individual third carbon layers 404c and the four individual fourth carbon layers 404d, which are in each case only connected to one spacer 103. After the selective removal of the sacrificial layer, the result is then the structure shown in FIG. 4A and FIG. 5 with overhanging top electrodes 404a, 404b, 404c and 404d that are in each case supported by a spacer 103.

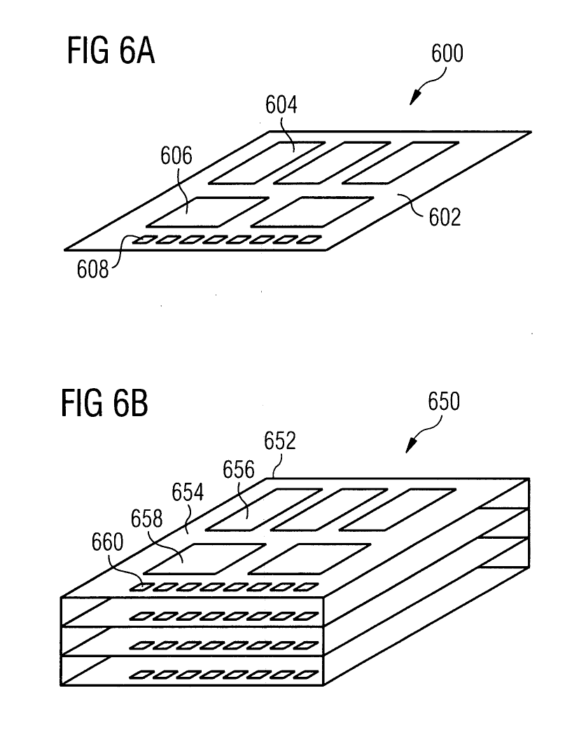

As shown in FIG. 6A and FIG. 6B, in some embodiments of the invention, integrated circuits or memory devices such as those described herein may be used in modules. In FIG. 6A, a memory module 600 is shown, on which one or more integrated circuits or memory devices 604 are arranged on a substrate 602. The memory device 604 may include numerous memory cells in accordance with an embodiment of the invention. The memory module 600 may also include one or more electronic devices 606, which may include memory, processing circuitry, control circuitry, addressing circuitry, bus interconnection circuitry, or other circuitry or electronic devices that may be combined on a module with a memory device, such as the memory device 604. Additionally, the memory module 600 includes multiple electrical connections 608, which may be used to connect the memory module 600 to other electronic components, including other modules.

As shown in FIG. 6B, in some embodiments of the invention, these modules may be stackable, to form a stack 650. For example, a stackable memory module 652 may contain one or more memory devices 656, arranged on a stackable substrate 654. The memory device 656 may include one or more memory cells in accordance with an embodiment of the invention. The stackable memory module 652 may also include one or more electronic devices 658, which may include memory, processing circuitry, control circuitry, addressing circuitry, bus interconnection circuitry, or other circuitry or electronic devices that may be combined on a module with a memory device, such as the memory device 656. Electrical connections 660 are used to connect the stackable memory module 652 with other modules in the stack 650, or with other electronic devices. Other modules in the stack 650 may include additional stackable memory modules, similar to the stackable memory module 652 described above, or other types of stackable modules, such as stackable processing modules, control modules, communication modules, or other modules containing electronic components.

Although the invention has been shown and described primarily in connection with specific exemplary embodiments, it should be understood by those skilled in the art that diverse changes in the configuration and the details thereof can be made without departing from the essence and scope of the invention as defined by the claims below. The scope of the invention is therefore determined by the appended claims, and the intention is for all alterations that lie within the range of the meaning and the range of equivalence of the claims to be encompassed by the claims.

What is claimed is:

1. An integrated circuit having a memory device, the memory device comprising:
at least one electrically conductive layer formed in or on a substrate;
at least one spacer formed on the substrate in such a way that the at least one electrically conductive layer is arranged alongside the at least one spacer; and
at least one carbon layer formed at least over a partial region of the substrate, wherein the at least one carbon layer crosses the at least one electrically conductive layer;
wherein the at least one carbon layer is at least partly formed on the at least one spacer in such a way that an interspace is formed between the at least one carbon layer and the at least one electrically conductive layer crossed by the at least one carbon layer; and
wherein the at least one carbon layer is configured in such a way that it can be brought into contact with the at least one crossed electrically conductive layer.

2. The integrated circuit as claimed in claim 1, wherein the substrate comprises a dielectric material.

3. The integrated circuit as claimed in claim 1, wherein the at least one electrically conductive layer is formed as an electrically conductive carbon layer.

4. The integrated circuit as claimed in claim 1, wherein the at least one electrically conductive layer comprises a refractory material.

5. The integrated circuit as claimed in claim 4, wherein the at least one electrically conductive layer comprises a material selected from the group consisting of tantalum, tantalum nitride, titanium, titanium nitride and molybdenum.

6. The integrated circuit as claimed in claim 1, wherein the at least one spacer comprises a carbon material or a refractory material.

7. The integrated circuit as claimed in claim 1, wherein the at least one spacer comprises a material selected from the group consisting of titanium, tantalum, tungsten, silicon nitride, and a carbide material.

8. The integrated circuit as claimed in claim 1, wherein the at least one spacer has a thickness of approximately 1 nm to 100 nm.

9. The integrated circuit as claimed in claim 1, wherein the at least one carbon layer comprises an electrically conductive carbon material.

10. The integrated circuit as claimed in claim 1, wherein the at least one carbon layer has a thickness of approximately 1 nm to 100 nm.

11. The integrated circuit as claimed in claim 1, wherein the memory device comprises:
a plurality of electrically conductive layers formed in or on the substrate;
a plurality of spacers formed on the substrate in such a way that each of the plurality of electrically conductive layers is arranged between at least two spacers; and
a plurality of carbon layers;
wherein the plurality of electrically conductive layers, the plurality of spacers and the plurality of carbon layers are arranged in such a way that a crossbar array is formed.

12. The integrated circuit as claimed in claim 11, wherein, in each case, two adjacent spacers of the plurality of spacers have a lateral spacing of approximately 5 nm to 1000 nm.

13. A method of producing a memory device, the method comprising:
forming at least one electrically conductive layer in or on a substrate;
forming at least one spacer on the substrate in such a way that the at least one electrically conductive layer is arranged alongside the at least one spacer; and
forming at least one carbon layer at least over a partial region of the substrate, wherein the at least one carbon layer crosses the at least one electrically conductive layer;
wherein the at least one carbon layer is formed on the at least one spacer in such a way that an interspace is formed between the at least one carbon layer and the at least one electrically conductive layer crossed by the at least one carbon layer; and
wherein the at least one carbon layer is configured in such a way that it can be brought into contact with the at least one crossed electrically conductive layer.

14. The method as claimed in claim 13, wherein the at least one carbon layer is formed from an electrically conductive carbon material.

15. The method as claimed in claim 13, wherein the at least one carbon layer is formed by a deposition method.

16. The method as claimed in claim 13, wherein the at least one carbon layer is patterned using a lithography method or an etching method.

17. The method as claimed in claim 13, wherein the at least one carbon layer is patterned using a lithography method and an etching method.

18. The method as claimed in claim 13, wherein, prior to the formation of the at least one carbon layer, at least one sacrificial layer is formed on the substrate or on the at least one electrically conductive layer.

19. The method as claimed in claim 13, wherein, prior to the formation of the at least one carbon layer, at least one sacrificial layer is formed on the substrate and on the at least one electrically conductive layer.

20. The method as claimed in claim 18, wherein the interspace between the at least one carbon layer and the at least one electrically conductive layer crossed by the at least one carbon layer is effected by removal of the at least one sacrificial layer.

21. The method as claimed in claim 19, wherein the interspace between the at least one carbon layer and the at least one electrically conductive layer crossed by the at least one carbon layer is effected by removal of the at least one sacrificial layer.

22. The method as claimed in claim 20, wherein the removal of the at least one sacrificial layer is effected with the aid of a wet etching method.

23. The method as claimed in claim 21, wherein the removal of the at least one sacrificial layer is effected with the aid of a wet etching method.

24. The method as claimed in claim 13, wherein
forming at least one electrically conductive layer comprises forming a plurality of electrically conductive layers in or on the substrate;
forming at least one space comprises forming a plurality of spacers on the substrate in such a way that each of the plurality of electrically conductive layers is arranged between at least two spacers; and
forming at least one carbon layer comprises forming a plurality of carbon layers;
wherein the plurality of electrically conductive layers, the plurality of spacers and the plurality of carbon layers are arranged in such a way that a crossbar array is formed.

25. A memory module, comprising:
a plurality of integrated circuits, wherein at least one integrated circuit of the plurality of integrated circuits comprises a memory device, the memory device comprising:
at least one electrically conductive layer formed in or on a substrate;
at least one spacer formed on the substrate in such a way that the at least one electrically conductive layer is arranged alongside the at least one spacer;
wherein at least one carbon layer formed at least over a partial region of the substrate, the at least one carbon layer crosses the at least one electrically conductive layer;
wherein the at least one carbon layer is at least partly formed on the at least one spacer in such a way that an interspace is formed between the at least one carbon layer and the at least one electrically conductive layer crossed by the at least one carbon layer; and
wherein the at least one carbon layer is configured in such a way that it can be brought into contact with the at least one crossed electrically conductive layer.

26. The memory module as claimed in claim 25, wherein the memory module is a stackable memory module in which at least some integrated circuits of the plurality of integrated circuits are stacked one above the other.
